(19) United States
(12) Patent Application Publication
(10) Pub. No.: US 2013/0222991 A1
(43) Pub. Date: Aug. 29, 2013

(54) APPARATUS, SYSTEM AND METHOD FOR CHARGING OR INTERCONNECTING MULTIPLE DEVICES USING A SINGLE MOBILE DEVICE COVER

(71) Applicant: Thomas J. McWilliams, Bryn Mawr, PA (US)

(72) Inventor: Thomas J. McWilliams, Bryn Mawr, PA (US)

(21) Appl. No.: 13/445,024

(22) Filed: Apr. 12, 2012

Related U.S. Application Data
(60) Provisional application No. 61/634,400, filed on Feb. 27, 2012.

(51) Int. Cl. H05K 7/00; G06F 1/16

(52) U.S. Cl. 361/679.4; 361/679.01

(57) ABSTRACT

An apparatus, system and method of providing and/or using at least a portable, protective cover, cradle, or the like for a mobile device, wherein a battery (or batteries) within the cover is capable of providing a back-up charge or recharge not only to the device covered, but additionally to a second one or more devices not typically physically associated with the device covered or with the device's cover.

### CROSS REFERENCE TO RELATED APPLICATION

This application claims priority to U.S. Provisional Patent Application Ser. No. 61/634,400, filed Feb. 27, 2012, the entirety of which application is incorporated herein by reference as if set forth in its entirety

### BACKGROUND OF THE INVENTION

1. Field of the Invention

The present invention is directed to mobile devices, and, more particularly, to an apparatus, system and method for charging and/or interconnecting multiple mobile devices using a single mobile device cover, which cover may include at least one battery.

2. Description of the Background

The use of smartphones, tablet computers, and other mobile devices has drastically increased in recent years. In 2010, over 90% of all American consumers had a mobile communication device. In fact, in 2010, it was estimated that over 30% of American consumers had more than one connected mobile device (wherein “connected” includes devices connected wirelessly, such as via WiFi and/or 3G/4G technologies), and this number is increasing by 5-10% year-on-year. Further, this number does not include wireless technologies that are often associated with mobile devices, such as Bluetooth headsets and peripherals, or infrared peripherals, for example. Moreover, nearly all of these wireless devices, and a great number of wireless peripherals used for and with these wireless devices, are powered by rechargeable batteries. “Rechargeable batteries,” as used herein, includes any devices and/or circuits capable of delivering a charge and capable of accepting a recharge.

Recharging of batteries has become more problematic for consumers as the power consumption of mobile devices has increased. The functionality, screen effects (brightness, clarity, etc.), inclusion of data and voice exchange capabilities, and availability of certain types of content and content streaming, among other reasons, have all caused battery power to drain, and thus have required more frequent and stronger recharges, than did prior generations of mobile devices. Moreover, as the use of multiple devices by a single consumer has increased, so too has the frequency of having one or more of the user's devices lack the power to perform desired tasks at desired times.

Most recharging of batteries is done using equipment provided with, or for use with, the wireless device or peripheral. Such recharging equipment may or may not employ proprietary connectors, i.e., connectors unique to particular manufacturers to plug into those manufacturers' devices alone. That is, plugging in a device having a proprietary connector for recharging typically occurs using a plug having, on an end opposing a wall plug or vehicle plug, that proprietary connector. Other devices may use standardized connectors for recharging, such as USB ports, mini-US ports, fire wire ports, or the like, by way of non-limiting example. Consequently, typical recharging is inconvenient and takes up space, plugs (in a house or vehicle), and time, and these disadvantages do not consider the need of the user to transport the recharging plugs with the user wherever the user goes. This problem is, of course, exacerbated by the proliferation of users using multiple mobile devices.

Many wireless devices may be recharged using inductive charging, without need of plugs or proprietary connectors. Inductive charging uses an electromagnetic field and inductive coil coupling to transfer energy. Energy is sent through the inductive coupling by the magnetic field to the device, which then uses that energy to recharge batteries, for example. There is typically a small gap between the coils employed in the sender and receiver of the energy, and thus inductive charging may be considered a “wireless” energy transfer because it frees the user from using wires to transfer the charge from the charging unit to the recharging device.

Induction chargers typically use an induction coil to generate the aforementioned electromagnetic field from within a charging unit. A second induction coil in the portable device takes power from the electromagnetic field and converts it to electrical current to charge the battery. The two induction coils thus combine to form an electrical transformer that wirelessly transfers the charging energy from one device to the other.

In the presently available art, various efforts have been made to provide users with the ability to charge one or more mobile devices using inductive charging. For example, the “Power Mat” includes a portable mat that unrolls to allow up to six mobile devices to be placed thereon and recharged. However, such inductive chargers nevertheless require that at least the charger be plugged in, and further require that the user thus carry the inductive charger and its plug, independent of the mobile device that is also to be carried.

An alternative solution to the recharging problem discussed above has been to provide backup batteries for the on-board battery of a mobile device. More particularly, there are now widely available backup batteries that are conveniently built into device “covers,” which are frequently used to at least partially surround mobile devices, such as for decorative purposes and/or to protect such mobile devices. Many of these “charging covers” can significantly extend the charge life for device use, and some charging covers include the proprietary connector built into the charging cover, such as to allow for convenient association of the battery within the cover with the device. Such charging covers do not typically recharge the device battery, but rather solve the issues discussed above by providing a secondary source of power once the device's on-board battery has appreciably expired.

However, such charging covers do not solve the de-charging/recharging problem for users having multiple mobile devices. Additionally, such device charging covers do not provide a solution to charge a device, selected by the user, for which the user may urgently need power. More particularly, such currently available charging covers do not provide a solution for charging any devices other than the device for which they are designed, i.e., other than the device for which the charging device includes a proprietary connector.

Additional disadvantages are present in the available art as pertains to data exchange. For example, in the event data is to be exchanged between devices, such as between a smartphone and a laptop, additional user equipment, such as interconnecting cords, must be readily available. Alternatively, data may be exchanged using wireless protocols, such as Bluetooth, infrared, near field communications (“NEC”) or the like, but in such cases the user must typically be familiar with the manner of the protocol on both devices between which the data is to be exchanged.

Therefore, the need exists for an apparatus, system and method for a device that need not always be plugged in, and that is capable of charging, and/or exchanging data between, multiple different mobile devices, simultaneously and/or at the selection of the user.

### SUMMARY OF THE INVENTION

The present invention is and includes at least a portable, protective cover, cradle, or the like for a mobile device, wherein a battery (or batteries) within the cover is capable of providing a back-up charge or recharge not only to the device covered, but additionally to a second one or more devices not typically physically associated with the device covered or with the device's cover. Further, in certain exemplary embodiments, the charging cover need not be plugged in to provide the back-up charge or recharge.

Further, the present invention is and includes at least a cover having at least two ports, namely an internal port for the cover to provide a connection to a covered device, and one or more ports facing outward from the cover, wherein one or more of the outward facing ports may be extendible port, such as a USB male connector, that is typically housed at least substantially within cover, and that is thereafter, such as upon actuation of an actuator, extended outward from the cover to interconnect with a secondary device, such as a laptop, desktop, secondary smartphone or tablet computer, or the like. The extendible port may serve as a charging port, and/or may serve as a data port, such as for interconnecting of disparate devices (wherein one of the devices may be the covered device), such as for data exchange, data dump, or the like as between the disparate devices.

Thus, the present invention provides an apparatus, system and method for a device that need not always be plugged in, and that is capable of charging, and/or exchanging data between, multiple different mobile devices, simultaneously and/or at the selection of the user.

### BRIEF DESCRIPTION OF THE DRAWINGS

Understanding of the disclosure will be facilitated by consideration of the following detailed description of the embodiments, taken in conjunction with the accompanying drawings, in which like numerals refer to like parts and in which:

FIG. 1 is a schematic diagram illustrating an exemplary multi-port charging cover in accordance with the present invention;

FIG. 2 is a block diagram illustrating an exemplary multi-port charging cover in accordance with the present invention;

FIG. 3 is a flow diagram illustrating a method of providing and/or using a multi-port charging cover in accordance with the present invention;

FIG. 4 is a schematic diagram illustrating an exemplary multi-port cover in accordance with the present invention; and

FIG. 5 is a flow diagram illustrating a method of providing and/or using a multi-port cover in accordance with the present invention.

### DETAILED DESCRIPTION OF THE INVENTION

It is to be understood that the figures and descriptions of the present invention have been simplified to illustrate elements that are relevant for a clear understanding of the present invention, while eliminating, for the purposes of clarity, many other elements found in typical telecommunications, protective, and charging apparatuses, systems and methods. Those of ordinary skill in the art will recognize that other elements are desirable and/or required in order to implement the present invention. However, because such elements are well known in the art, and because they do not facilitate a better understanding of the present invention, a discussion of such elements is not provided herein.

The present invention is and includes at least a portable, protective cover, cradle, or the like for a mobile device, wherein a battery within the cover may be capable of providing a back-up charge or recharge not only to the device covered, but additionally to a second one or more devices not typically physically associated with the device covered or with the device's cover. Further, in certain exemplary embodiments, the charging cover need not be plugged in to provide the back-up charge or recharge. Further, the cover may be capable of providing data exchange capabilities, with or without charging capabilities, between devices associated with the ports of the cover.

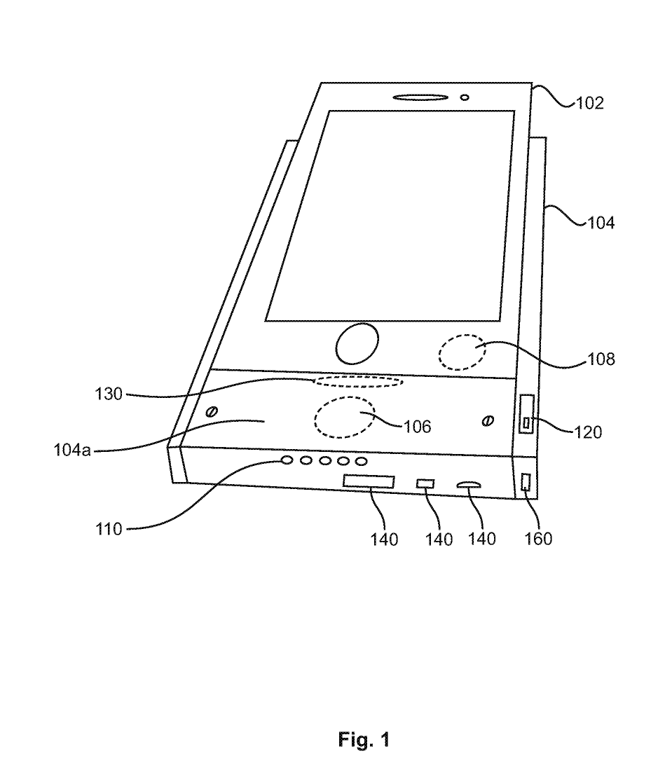

More particularly, as shown in FIG. 1, a device 102, such as a smartphone, tablet computer, or like mobile device, 102 may be covered, at least partially, with the cover 104 of the present invention. The cover may have, such as embedded therein and preferably partially or fully contained thereby, one or more rechargeable batteries 106, wherein the one or more batteries are preferably associated with the battery 108 of the underlying device 102, such as by, for example, being connectively associated with a plug 130 internal to the cover that plugs into the device, or by providing access for electrical current to flow into the battery of the covered device, such as by induction. Thereby, in any manner of association, the secondary battery 106 embedded within the cover 104 is preferably capable of charging the rechargeable battery of the covered device 102.

The cover 104 may be, for example, flexible, and thus formed of rubber or rubberized plastic, by way of non-limiting example, or may be rigid, and thus formed of metal or plastic, by way of non-limiting example. The cover 104 may be partially covering, such as to allow the cover to slide on from the bottom of the device (and to thereby place a male plug within the cover into a female receptacle at the bottom of the mobile device), or from the top or sides of the device, or may be substantially or totally covering of the non-interactive portion (such as the bottom, top, sides and back) of the device. In a substantially or totally covering embodiment, it may be preferable that the cover be flexible, such that it may be stretched over in order to fit snugly about the device. The cover may include an insertion point, battery compartment, and/or overlay 104a for the battery 106. Likewise, the battery overlay 104a may be flexible or rigid, apart from the underlying cover, and may, in certain embodiments, allow for ready access to, and removal and replacement of, battery 106. The cover 104, and preferably the combination of cover 104 and battery 106 and battery compartment 104a, may have a minimal form factor, and this may preferably be the case in the embodiments discussed below, including those exemplary embodiments providing one or more ports and/or extendible ports.

The battery 106 may be readily removable or replaceable by any means known. Additionally, the battery 106 may be rechargeable by any means known. For example, the cover may include solar cells that allow recharging of the battery 106. In addition to, or independent of, solar cells, the cover may have associated therewith an outlet 160 to allow a plug (such as a wall plug or a vehicle plug) to be associated with the cover to recharge the battery 106, and/or the battery 106 may be readily removable and may have associated therewith an outlet to allow a plug to be associated directly with the battery. Additionally and alternatively, the cover may have associated therewith disposable batteries, either independent of or in association with the rechargeable batteries 106, such as to increase the convenience of the user in providing power to the covered device even in circumstances where a charge for the battery 106 within the cover is not available. The constitution of the battery may be of any makeup apparent to those skilled in the art in light of the purposes disclosed and the discussion herein.

Further, the cover 104 may include one or more indicators 110 of the battery level of the battery 108 of the underlying device, and/or of the battery 106 of the cover, or may not include such indicators. Such indicator may be manually activated by the user and/or may be displayed automatically when, for example, battery 106 detects a charge. The cover 104 may further include one or more actuators 120 accessible to the user, whereby the user may or may not be enabled to open the charging circuit from the secondary battery 106 embedded in the cover 104 to the covered device 102. As would be understood by those skilled in the art, an indicator of battery levels and/or a user actuatable element to allow for charging using the secondary battery 106 to occur may also reside in the software of the underlying covered device.

Further, in electrically connective association with the embedded battery or batteries, the cover may include one or more additional ports 140 (in addition to the proprietary or non-proprietary connector/plug 130 within the cover and connected directly to the covered device). Such additional ports 140 may be proprietary or non-proprietary ports, male or females ports, or the like. The additional ports 140 may be external to the cover, such as along the bottom, top and/or side faces of the cover, or may be on the back of the cover, and may be physical ports or effective ports. For example, the additional ports 140 may be USB or mini-USB ports, and/or one or more inductive charger locations, such as a “proximity” charger, associated with the back of the cover and facing away from the covered device. There may be no additional ports 140, up to any number of additional ports 140 as can be physically accommodated by the cover and as could be electrically supported by the secondary battery.

The additional charging ports must be electrically connected with the battery or batteries embedded within the device cover. Further, as referenced above with respect to the main charging plug for the covered device, these secondary charging ports may likewise be associated with indicators of the charge level of a secondary, non-covered device associated with the cover, and/or with indicators of the charge capability of the secondary battery for the secondary non-covered device. Alternatively, such secondary indicators may not be present. Likewise, one or more actuators to allow activation by the user of the charging of the one or more secondary, uncovered devices, upon indication to affect the charging by the user, may or may not be provided.

The additional ports 140 may further be associated with at least one capacitor or like element and/or delimiting circuit, which may allow for delivery of a specific voltage suitable for the at least battery 108 of the underlying device, such as wherein the underlying device may not accept a charge from a charger having an incompatible voltage/wattage. For example, a generic charger for a Motorola® cellular phone may not properly charge the Motorola® battery if a different charging voltage than expected by the device is detected. This is, some devices require a specific voltage to properly charge and/or to prevent over-charging of the battery, such as in an effort to dictate that user's purchase a particular manufacture's approved equipment. Thus, the aforementioned delimiting circuit capacitor may be quasi-universal, at least in that it may provide the capability to isolate between different known voltages required by popular manufactures, such as responsive to the type of device placed at the one or more ports discussed herein.

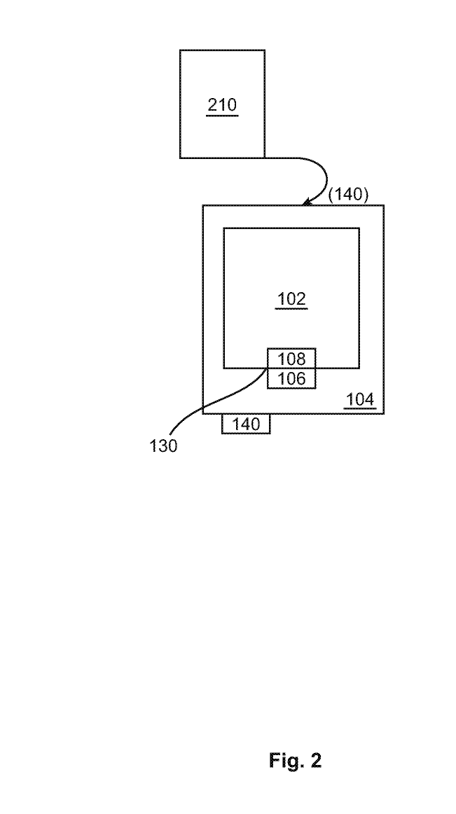

FIG. 2 is a block diagram illustrating an exemplary embodiment of the present invention. In the embodiment illustrated, a smartphone 102 is placed within the cover, and the embedded battery 106 within the cover is placed adjacent to the battery 108 in the underlying smartphone, such that the cover provides capability for proximity charging of the battery of the covered smartphone. Moreover, in the illustrated embodiment of FIG. 2, a second device 210 (such as a computing tablet in the illustrated embodiment) is placed against the side of the cover that is opposite the side of the cover immediately adjacent to the smartphone. Further, the illustrated computing tablet is placed such that proximity charging of the battery of the computing tablet may occur from the embedded battery of the cover.

Those skilled in the art will appreciate, in accordance with FIG. 2 and with the discussion herein, that one or both of the illustrated devices may, rather than being associated with the proximity charge from the embedded battery of the cover, be associated with a plug whereby the battery of either device receives a charge or recharge from the embedded battery within the cover through the plug. Additionally, those skilled in the art will appreciate that multiple secondary devices may be charged in accordance with the cover of the present invention, and that such devices may be provided with like recharging ports, or may be provided with dissimilar recharging ports, such as wherein an embodiment includes a mini-USB recharging port, a USB recharging port, and/or a proximity charger for a secondary device not covered by the cover.

Those skilled in the art will further appreciate in light of the discussion herein, that the battery embedded within the cover may preferably have a smaller profile, a smaller weight, and the like, as compared to other available batteries, such that the cover will not add appreciably to the profile of the covered device, and such that the cover will not add appreciably to the weight of the covered device. However, those skilled in the art will appreciate that the battery or batteries provided within the cover should be sufficient to provide a not insubstantial charge to at least one of the covered device and the at least one secondary device, such that the embedded battery or batteries will well serve as at least a “back-up” battery for emergency use. Of course, it may be preferable that the cover of the present device include capability to provide a substantial charge or recharge, or that the cover of the device provide sufficient strength in the secondary battery to charge multiple devices simultaneously. Further, use of certain charge or recharge aspects of the secondary battery, such as use of the inductive proximity charger, if present, on the back of the cover may require that the cover be plugged in.

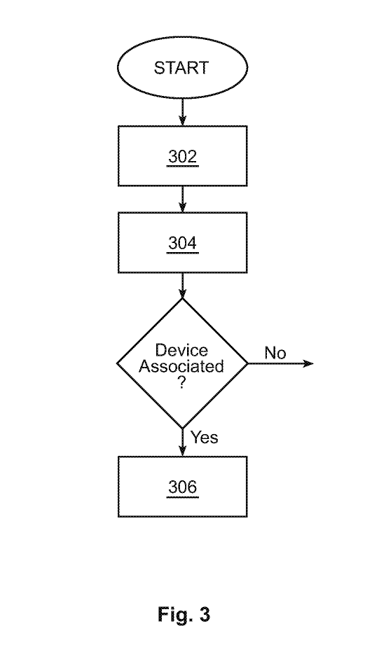

FIG. 3 illustrates an exemplary method 300 in accordance with the present invention. At step 302, a mobile device cover is provided having at least a charging port for the device covered, and one other charging port. As discussed above, the charging ports, as used herein, may include inductive charging capabilities.

At step 304, a battery compartment for at least one replaceable, preferably rechargeable battery is provided within the cover. At step 306, a charging capability is provided whereby, upon association by the user of a continuous electrical connection between the battery and one or more devices associated with one or more the at least two ports, such as responsive to a user actuation, an electrical charge flows from the battery within the cover to the at least one device connected to at least one of the at least two ports, thus charging or recharging a battery physically associated with the device charged.

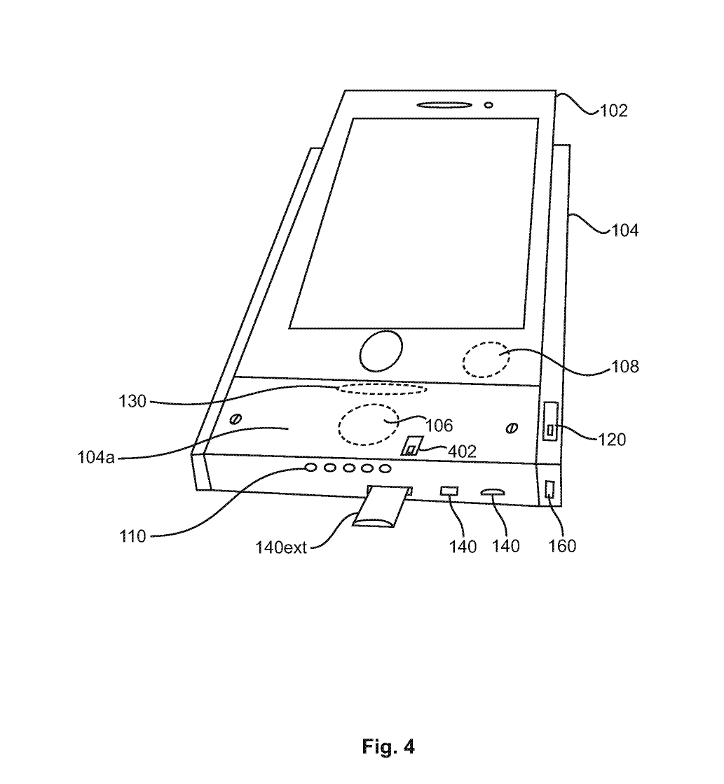

FIG. 4 is a schematic diagram illustrating a cover 104 having at least two ports, namely the internal port 130 for the cover to provide a connection to the covered device, and one or more ports 140 facing outward from the cover. In the illustrated embodiment, one or more of the outward facing ports may be extendible port 140ext (i.e., may be a “flip out” port), such as a USB male connector, that is typically housed at least substantially within cover 104, and that is thereafter, such as upon actuation of an actuator 402 by a user, extended outward from the cover to interconnect with a secondary device, such as a laptop, desktop, secondary smartphone or tablet computer, or the like. In certain exemplary embodiments herein, port 140ext need not extend from the housing/cover, but may nevertheless serve the charging function for the covered device, and/or the data exchange function discussed below for the covered device, as will be understood to those skilled in the art in light of the discussion herein.

Such extendible port 140ext may serve as a charging port, as discussed hereinabove, and/or may serve as a data port. For example, port 140ext may allow for interconnecting of disparate devices (wherein one of the devices is preferably the covered device), such as for data exchange, data dump, or the like as between the disparate devices. Thereby, multiple devices may be connected to a computer or like device, such as for data exchange with the computer, and/or with the covered device, and/or with other devices associated with ports 140, and/or for charging. In such embodiments, there may or may not be a battery 106 associated with cover 104.

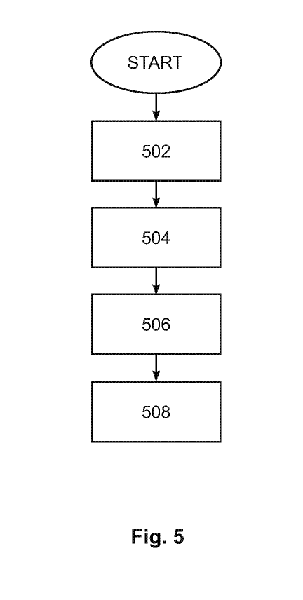

FIG. 5 is a flow diagram illustrating a method of providing and use of the cover of the present invention as a data port. As step 502, a cover having associated therewith a plurality of ports is provided. At least one of the plurality of ports is provided as extendible at step 504. At least the extendible port is capable of association with a data exchange location, such as a computer, at step 506. Other devices associated with others of the ports are also provided as capable of data exchange with the data exchange location via communicative electrical connection within the cover to the extendible port at step 508.

Although the invention has been described and pictured in an exemplary form with a certain degree of particularity, it is understood that the present disclosure of the exemplary form has been made by way of example, and that numerous changes in the details of construction and combination and arrangement of parts and steps may be made without departing from the spirit and scope of the invention.

What is claimed is:

1. A protective cover for at least partially covering a mobile device, comprising:
a battery inlay capable of receiving and holding at least one rechargeable battery;
at least two electrical ports electrically connected to said battery, wherein at least one of the at least two ports is capable of physical association with an electrical connector of the mobile device, and wherein another of the at least two ports is capable of physical association with a second electrical connector of a second mobile device.

2. A cover for at least partially covering a mobile device, comprising:
an at least partially flexible cradle for covering at least a portion of the non-screen portion of the mobile device;
at least two ports embedded within said cradle, wherein at least a first of the at least two ports is physically and communicatively connected with the mobile device, and wherein at least a second of the at least two ports faces outwardly from said cradle away from the mobile device and is communicatively connected to at least the first port;
an actuator, wherein, upon actuation of said actuator, the second port is extended outward from said cradle for physical association with at least a second device.

3. The cover of claim 2, wherein the communicative connection comprises at least a data exchange connection.

4. The cover of claim 2, wherein the communicative connection comprises at least a charging connection.
